(19) United States
(12) Patent Application Publication
(10) Pub. No.: US 2005/0162832 A1
(43) Pub. Date: Jul. 28, 2005

(54) Heat dissipation in devices that have an internal energy supply

(76) Inventors: Jens Muller, Tsingtauer Str (DE); Manfred Stefener, Kathreinweg (DE); Marcus Preissner, Schonstr (DE)

Correspondence Address: IP Strategies, Suite I, 12 1/2 Wall Street, Asheville, NC, 28801, US

(21) Appl. No.: 10/510,799

(22) PCT Filed: Mar. 28, 2003
(86) PCT No.: PCT/EP03/03371

(30) Foreign Application Priority Data
Apr. 10, 2002 (EP) 02008034.7

(51) Int. Cl. H05K 7/20

(52) U.S. Cl. 361/699

(57) ABSTRACT

The invention relates to heat dissipation with devices with an internal energy supply device. A housing device for an electrical load and an energy supply device are provided, especially a laptop housing, having a device for heat dissipation in order to transport the heat generated by the energy supply device by means of at least one flowing medium to at least one outer surface of the housing device and to discharge it via the outer surface.

### FIELD OF THE INVENTION

The invention relates to the heat dissipation of electrical devices which are operated with an internal energy supply, in particular with a fuel cell device. A main field of use for the invention is portable computers.

### STATE OF THE ART

Generally, small electrical devices are supplied with current from non-rechargeable or rechargeable batteries located in the housing. The objective in the initial and on-going development of mobile electrical devices has two main features: the maximum possible performance in a device which is as compact as possible. The requirement for compactness gives rise to ever smaller outer dimensions and/or a flat construction with correspondingly small outer surfaces, by means of which the heat generated by the loads in the interior of the housing must be dissipated. The cooling of the energy supply device has received little attention until now, because with non-rechargeable and rechargeable batteries, this does not play a significant role due to the low amount of inherent heat generated.

Even though a network-independent energy supply with non-rechargeable/rechargeable batteries is currently the normal case, with increasingly high performance consumer loads, increasingly high performance energy supply devices must be made available which are more suitable for long-term operation. With the rapid rate of development of fuel cells recently, a more significant emerging trend is the realisation of the energy supply of these types of electrical devices using fuel cells instead of non-rechargeable/rechargeable batteries.

With the use of fuel cells for small electronic devices the heat generated by the internal energy source is however not negligible compared to the heat generated by the loads. Consequently, the problem of heat dissipation (“cooling”) becomes more pronounced.

It should be pointed out at this point that in this application the terms “heat dissipation” and “cooling” are used synonymously in accordance with the usual language used in the technology. A prime example of the problem outlined above are portable computers (notebooks, laptops, PDAs, organisers, etc.), which, for the sake of simplicity and without restricting generality, are referred to as laptops. Therefore, the invention is explained essentially with reference to the field of use of the portable computer for which it is particularly predestined. However, it should be understood that the invention is not restricted solely to this field. In particular, mobile telephones of primarily the new generation of internet-compatible mobile telephones and also portable equipment with monitors (portable televisions, measurement devices, medical equipment for the emergency services, etc.) are fields of use for the invention.

The core of the computer is the electronics and in particular the processor, for which adequate cooling is an absolute necessity and which accordingly exhibits a high state of development. That which makes the portable computer a particularly suitable field of use is its flat construction. In comparison to its volume, the portable computer has a large surface, which in the operating state is almost doubled due to the fold-out swivelling screen.

FIG. 1 is a schematic view of a conventional portable computer with hinged screen section. The four outer surfaces of the laptop which dominate from a size point of view are numbered from 1 to 4: 1 designates the bottom surface of the base plate of the laptop, 2 the upper side of the base plate of the laptop, mainly taken up by the keyboard, and 3 and 4 are the front and back of the hinged screen lid respectively.

For various reasons, with the laptops currently available on the market none of these four surfaces play a significant role in heat dissipation. The bottom surface 1 is only conditionally suitable, because the heat dissipation requires air circulation with the ambient air. The surface 2 on the keyboard side is largely taken up by the keyboard and other operating controls, whereby the keys and other operating surfaces are not well suited to heat dissipation due to construction and/or operational reasons. The hinged screen lid would be particularly suitable for heat dissipation, in particular the back 4. However, in this case the heat needs to be transported from the housing part exhibiting the processor to the screen lid, which can only be ensured in an adequate manner by a flowing medium. Although consideration is taking place in this direction, cf. for example U.S. Pat. No. 5,383,340 and U.S. Pat. No. 5,634,531, these concepts have not become established due to the substantial technical complexity. An alternative is the provision of the active electronic loads in the screen lid, which has also been suggested in U.S. Pat. No. 5,383,340 and in the U.S. Pat. No. 6,181,555 and U.S. Pat. No. 5,982,617. Therefore generally, processors are only cooled by a fan through a ventilation hole L in the small rear outer surface of the laptop housing.

Therefore one object of the invention is the effective dissipation of heat generated by the operation of the energy supply device in electrical devices with an internal energy supply device.

In particular an object of the invention is to improve the possible uses of fuel cells for the energy supply of electronic devices.

### DESCRIPTION OF THE INVENTION

The objects described above are solved according to the invention by the housing device with the features of Claim 1.

Accordingly, the housing device, which provides accommodation for an electric load and its energy supply device, comprises a device for heat dissipation in order to transport the heat generated by the energy supply device by means of at least one flowing medium to at least one outer surface of the housing device and to discharge it via the outer surface.

For the dissipation of heat from the energy supply device to the outer surface, heat transport by means of a flowing medium is substantially more efficient than (electronic and/or phononic) thermal conduction or thermal radiation. Both of the latter processes can though provide a supporting contribution, in particular with the uniform distribution over the outer surface (thermal conduction) and with the discharge to the ambient surroundings (thermal radiation).

Since “housing” is usually taken to signify a rigid outer envelope with a specific and non-varying outer shape, here the general expression “housing device” is used, which is intended to indicate that the invention can be used not only for simply formed housings, but also for housing devices of many housing parts connected together and optionally movable relative to one another. Particularly, it is with such housing devices that the concept according to the invention can be realised especially advantageously.

Whereas in conventional housing devices with an integral energy supply device, no particular consideration is given to the heat dissipation from the energy supply device and this at best occurs by means of the natural convection of the air in the housing device and thermal conduction through the housing parts, the invention provides for an active device for heat dissipation, which facilitates the use of energy supply devices with comparatively substantial generation of heat. The flowing medium (or one of the flowing media) can be the air available in the housing device. With fuel cells as the energy supply devices the flowing media can comprise their waste gases. In these cases the heat dissipating active device comprises, for example, one or more blowers with which far more effective air flows or gas flows can be created for heat dissipation than in comparison to natural convection. However, media provided specially for heat dissipation can also be used, for example in a cooling circuit or heat pipe.

Therefore, the device for heat dissipation in a particularly preferred further development of the invention comprises a pipe system for at least one flowing fluid providing thermal transport and integrated into the housing device.

This pipe system can be integrated into the wall of the outer surface(s) at least in the region of the outer surface(s) that are effectively thermally active, which has the constructional advantages in that the thermal transfer to the outer surface is improved and a more efficient exploitation of the interior space is facilitated.

In the region of the outer surface the pipe system can exhibit a distribution and/or meander structure in order to integrate a surface proportion as large as possible into the thermal discharge in order to increase the efficiency.

In an advantageous further development hinged and/or extractable devices are provided on or in the housing device, with the aid of which the surface of the housing device that can be used for the thermal discharge can be enlarged.

This further development is primarily practicable when the “intrinsic” outer surfaces are not suitable for thermal discharge or their area is not sufficient, i.e. in particular with compact devices with small outer surfaces.

Similarly, to increase the effectiveness of the thermal discharge it may be appropriate to provide the outer surfaces used for thermal discharge with surface-enlarging structural features: the surface enlargement can be achieved macroscopically by means of protruding elements such as cooling fins or by a corrugated surface, but also microscopically by means of an increased surface roughness and/or by a porous surface structure.

It is only pointed out and no detailed explanations are necessary to say that for increasing the effectiveness of heat dissipation the contribution due to heat radiation must under some circumstances also be taken into account. It may therefore be quite practicable to apply a coat of paint to the outer surfaces to improve the radiation emission.

Alternatively or in addition to this, the device for heat dissipation can comprise at least one fan (blower), in order to improve the air circulation—and therefore the heat transfer to the ambient surroundings—on at least one of the outer surfaces used for thermal discharge.

The concept according to the invention can be used with any electrical device with integral energy supply. It is however particularly practicable if this energy supply device is a fuel cell device or comprises one, because the heat generated by a fuel cell device is normally significantly higher than with comparable energy supply devices such as primary and secondary cells.

In an advantageous further development the device for heat dissipation is formed such that it is also suitable for dissipating the heat generated by the electrical load. This means for example that the pipe system for the flowing fluid can be routed past the electrical load and take up and dissipate the heat generated by the electrical load by means of suitable heat exchanging devices.

A particularly preferred field of use for the invention is the portable computer whose housing device can be retrofitted according to the features described above or—as is normally to be preferred—can be designed from the start according to these details. Apart from conventional portable computers, more or less significant variations in the arrangement of the housing parts can be preferred, some of which are quoted as preferred embodiments in the following description of the figures.

In particular with conventional portable computers, the back of the flat screen is especially suitable as an outer surface for heat dissipation, because it is comparatively large and also does not have any further functional task. Under some circumstances however the front of the screen can also be used for heat dissipation.

With a particularly preferred further development, which in particular simplifies the formation of the pipe system, the energy supply device is accommodated in the housing section which includes the screen. In this case the fluid does not need to be routed via various (swivelling) housing parts which move relative to one another.

Preferably, the device for heat dissipation is formed such that in addition to the cooling of the energy supply device, effective dissipation of the heat generated by the computer electronics (in particular the processor unit) is also achieved.

This means for example that in the case of a DMFC a fuel cell can be used as an energy supply device with discharge air at a temperature of 60° C. to cool the processor having a somewhat higher temperature.

The basic principles of the invention are explained in the following with reference to the enclosed figures based on a particularly suitable field of use for the invention, i.e. a portable computer powered by fuel cells.

The following are shown:

FIG. 1 a schematic view of a conventional portable computer;

FIG. 2 a schematic view of a first preferred embodiment of this invention;

FIGS. 3-5 schematic detail views for the practical implementation of the concepts on which the invention is based;

FIG. 6 a schematic view of a second preferred embodiment of this invention;

FIG. 7 a schematic view of a third preferred embodiment of this invention;

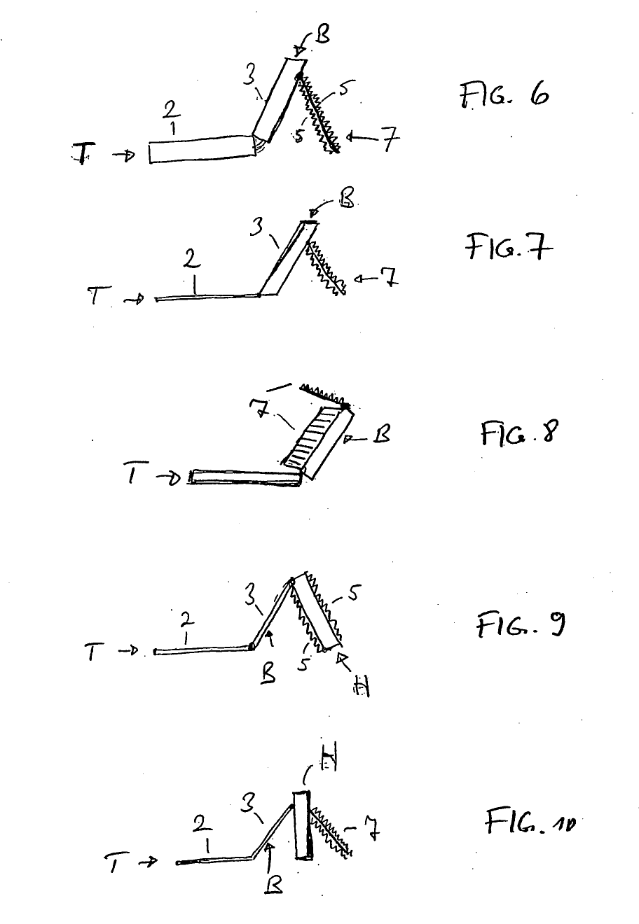

FIG. 8 a schematic view of a fourth preferred embodiment of this invention;

FIG. 9 a schematic view of a fifth preferred embodiment of this invention;

FIG. 10 a schematic view of a sixth preferred embodiment of this invention.

With regard to FIG. 1 the introduction to the description has already mentioned it. It shows a schematic view of a hinged portable computer with a housing section T lying on the table surface and a diagonally standing screen lid B. The figure is only used to show the structural conditions forming the basis on which the use of the invention on portable computers is based. Apart from the keyboard on the upper side 2, the housing section T generally contains all the essential components of the computer electronics and the energy supply device required for the electronics.

With a laptop powered by conventional rechargeable batteries the four large outer surfaces 1-4 of the hinged housing contribute to the heat dissipation of the heat generated during laptop operation, but this amount is not sufficient. Therefore, the processor is usually cooled by means of a fan via an air hole L in the back of the housing section T.

FIG. 2 shows a schematic view of a first preferred embodiment of this invention. In contrast to the laptop in FIG. 1, the laptop sketched in FIG. 2 is powered by a fuel cell device accommodated in the housing section T. In order to be able to dissipate the heat generated by the fuel cell device from the housing section T to a sufficient extent, the large surface of the free standing lid unit B is used.

In this respect the heat generated in the housing section T must be transported to the screen lid B. Preferably, the transport occurs by means of a flow medium which takes up the heat generated by the energy supply device in the housing section T, passes it from the housing section T by means of flow devices, of which only the schematically sketched flexible hose 6 is drawn in the figure, to the lid B and discharges it to the ambient surroundings.

Especially for the case where the energy supply device comprises a fuel cell device, the fluids used for the heat dissipation can comprise fluids used in the operation of the fuel cell device and/or reaction products occurring with it.

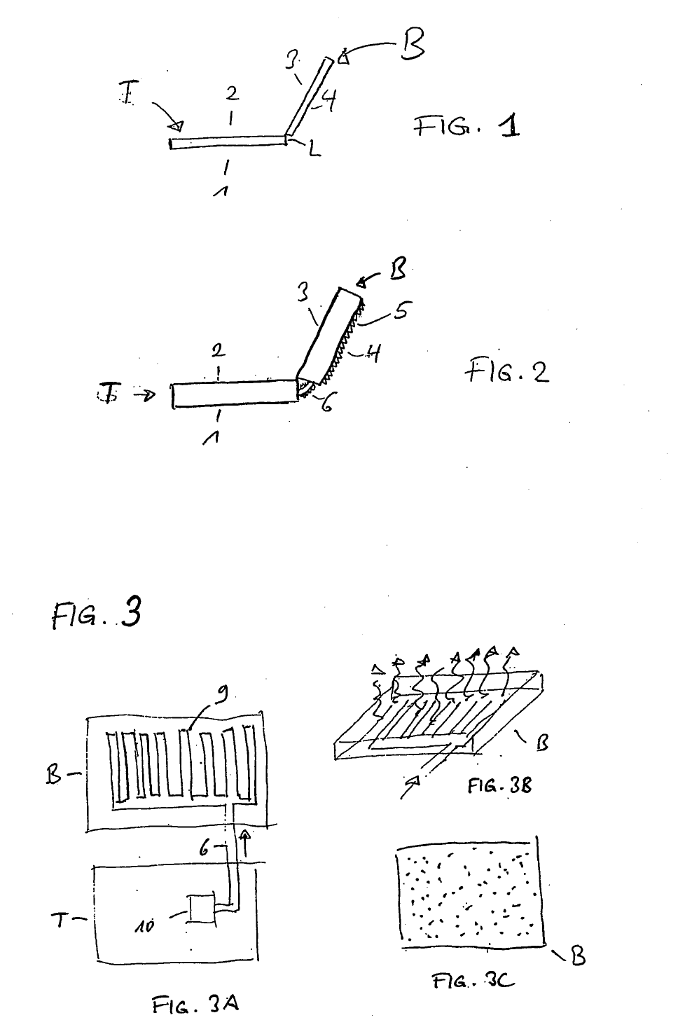

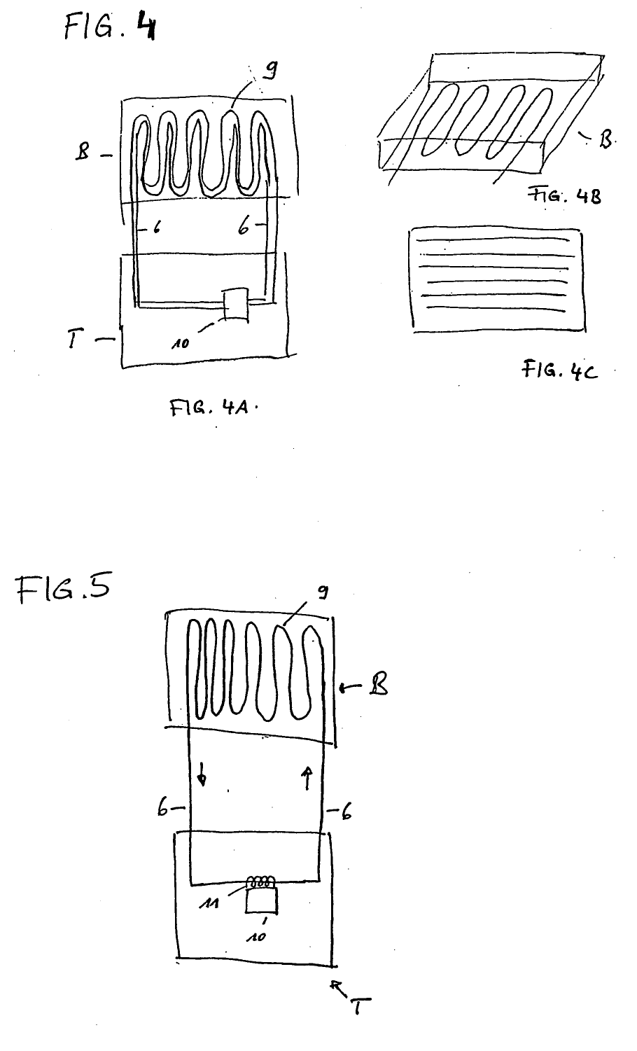

Two appropriate embodiments are sketched in FIGS. 3A-3C and 4A-4C (different views in each case).

First regarding FIG. 3: As indicated in FIG. 3A, heated (gaseous or liquid) fluid flows from the fuel cell 10 provided in the housing section T through the pipe 6 to the lid unit B, where it is distributed in the cover unit by means of a distribution structure 9, such that a surface as large as possible can be used for thermal discharge to the ambient surroundings, as indicated in FIG. 3B. Here, the heat dissipation can optionally occur—depending on the type and physical condition of the fluid—in that the fluid itself is discharged to the ambient surroundings, which for example in the cases of air, carbon dioxide and water vapour presents relatively little problem. In this case the area provided for the discharge, which is sketched in the plan in FIG. 3C, preferably exhibits a porous structure.

Also particularly suitable for heat dissipation is though a circulatory flow between the source of heat (fuel cell 10) and the heatsink (lid unit B), which is schematically indicated in FIG. 4A. This version is primarily preferable when, during the operation of the fuel cell, fluids are used which can be fed on the input side as well as (under some circumstances in a changed composition) occur on the output side. Examples of these types of fluids are water and air. For the efficient exploitation of the outer surface of the lid unit B a distributor structure 9 is provided in or immediately below the outer wall, for example in the form of a meander flow guide (cf. FIG. 4A, 4B). To improve the heat exchange with the ambient surroundings, surface-enlarging structures can be provided: for example the outer surface can exhibit a corrugated structure and/or be provided with fins (indicated in FIG. 4c).

The closed cooling circuit can also be independent of the energy supply device, which has the advantage that the fluids or fluid mixtures most suitable in the relevant temperature range can be used for heat dissipation. This type of arrangement is illustrated schematically in FIG. 5. Here, the heat dissipation occurs by means of a separate enclosed circuit, provided specifically, whereby the fluid flowing in this circuit takes up the heat generated by the energy supply device 10 by means of a heat exchanger 11—in the case of a fuel cell device for example in a counter-flow process with the heated fluids of the fuel cell device.

The type of heat dissipation described in FIGS. 4 and 5 can, with suitable fluids or fluid mixtures, be formed as a two-phase circuit, in which the liquid medium evaporates on taking up heat, flows in the gaseous state from the fuel cell 10 to the distributor structure 9, condenses there on discharging heat and is then fed back again in condensed form to the fuel cell 10.

With the description of the sketched examples it has been assumed that the natural convection occurring on the surface is sufficient for heat discharge to the ambient surroundings. However, if required, fans can be provided to reinforce the convection. If the housing section B exhibiting the screen is used for cooling (as described for example in conjunction with FIG. 2), then the screen side 3 can be thermally insulated from the back 4 acting as the cooling surface. If this is not necessary, or if—with low outdoor temperatures—heating of the screen is advantageous, then also the screen side 3 of the lid unit B can contribute to the heat dissipation.

FIG. 6 is a schematic view of a second preferred embodiment of the invention. In contrast (alternatively also additionally) to the embodiment shown in FIG. 2, here a separate cooling surface 7 is provided, which can be swivelled out from the lid unit B and provided on both sides with fins to reinforce the cooling effect. In the example illustrated this cooling surface 7 can be supported by the underlying surface, so contributing to the support of the lid unit B. The latter may primarily be desirable when the fuel cell device is integrated into the lid unit B.

Alternatively or in addition to the embodiments sketched in FIGS. 6 and 8-11, separate cooling surfaces can be provided which can be swivelled out to the side or to the front, as schematically indicated in FIG. 7. On discharging the heat, these cooling surfaces can be used for heating the ambient air in the front region of the screen surface, which improves the possible uses at low outdoor temperatures. At the same time these surfaces can be used as viewing shades, as guards against interfering light incident at the side and as protection of the screen against other ambient effects (e.g. rain drops, splashed water).

An effect of the cooling surface 7 supporting the screen B is primarily practicable when—as is illustrated by the embodiment of FIG. 8—both the energy supply device (for example a fuel cell device) and also the essential electronic components are integrated into the housing section B exhibiting the screen. In this case the unit T lying flat on the underlying surface need only exhibit the devices required for manual operation, in particular the keyboard and can therefore be constructed to be very flat, for example as a so-called touchpad.

FIG. 9 shows an embodiment based on similar principles as in FIG. 7, in which the electronics and the energy supply are integrated in one housing main section H. The screen and keyboard sections B and T can be swivelled out from this housing main section H and can be formed as thin layers or pads. The main housing H, which exhibits both the fuel cell device and the electronics, in this case stands diagonally and can alternatively contribute with one or both large housing surfaces to the heat dissipation. In the example in the sketch both large housing surfaces are provided with fins 5 for heat dissipation. The advantage of this embodiment is that the fluid does not need to be routed via swivelling axes.

FIG. 10 shows an alternative embodiment which also implements the principles of the embodiment of FIG. 7. The common swivelling screen unit B and keyboard unit T are fitted to one side of an upright standing main housing H, whereas on the other side the cooling surface 7 is fitted which also swivels and provides a supporting function.

This invention is particularly well-suited to those devices having swivelling large-area housing sections. The objective of the invention is to dissipate the heat generated by the internal energy supply device of an electrical device in an efficient manner. It should also be understood however that in addition to this, the heat generated by internal loads (processors, motors, etc.) can also be dissipated. The field of use can be extended to devices without large-area housing outer surfaces if they are equipped with swivelling and/or extractable surfaces or other devices (e.g. cooling coils) for the purposes of thermal dissipation.

1. Housing device for an electrical load and an energy supply device, comprising:
a device for heat dissipation to transport the heat generated by the energy supply device by means of at least one flowing medium to at least one outer surface of the housing device and to discharge it via the outer surface.

2. Housing device according to claim 1, in which the device for the heat dissipation comprises a pipe system integrated into the housing device for at least one flowing fluid providing the heat transport.

3. Housing device according to claim 1, with swivelling and/or extractable devices to enlarge the outer surface of the housing device usable for the heat dissipation.

4. Housing device according to claim 1, in which at least one of the outer surfaces used for the heat dissipation exhibits surface-enlarging structural features to improve the heat dissipation.

5. Housing device according to claim 4, in which the surface-enlarging structural features comprise an increased surface roughness and/or cooling fins and/or surface corrugation and/or a porous surface material.

6. Housing device according to one claim 1, in which the device for heat dissipation comprises at least one fan to improve the air circulation on at least one of the outer surfaces used for heat dissipation.

7. Housing device according to claim 1, in which the energy supply device comprises a fuel cell device.

8. Housing device according to claim 1, in which the device for heat dissipation is formed such that the heat generated by the electrical load can also be dissipated.

9. Portable computer with a housing device according to claim 1.

10. Portable computer according to claim 9, in which the outer surface used for heat dissipation comprises the front and/or back of a flat screen.

11. Portable computer according to claim 9, in which the energy supply device is provided in the housing section comprising the screen.

12. Portable computer according to claim 9, in which the device for heat dissipation is formed such that the heat generated by the electrical load can also be dissipated, and in which the device for heat dissipation is formed such that the heat generated by the computer electronics can also be dissipated.

13. Portable computer according to claim 10, in which the energy supply device is provided in the housing section comprising the screen.

14. Portable computer according to claim 10, in which the device for heat dissipation is formed such that the heat generated by the electrical load can also be dissipated, and in which the device for heat dissipation is formed such that the heat generated by the computer electronics can also be dissipated.

15. Portable computer according to claim 11, in which the device for heat dissipation is formed such that the heat generated by the electrical load can also be dissipated, and in which the device for heat dissipation is formed such that the heat generated by the computer electronics can also be dissipated.

16. Housing device according to claim 2, with swivelling and/or extractable devices to enlarge the outer surface of the housing device usable for the heat dissipation.

17. Housing device according to claim 2, in which at least one of the outer surfaces used for the heat dissipation exhibits surface-enlarging structural features to improve the heat dissipation.

18. Housing device according to claim 3, in which at least one of the outer surfaces used for the heat dissipation exhibits surface-enlarging structural features to improve the heat dissipation.

19. Housing device according to claim 2, in which the energy supply device comprises a fuel cell device.

20. Housing device according to claim 3, in which the energy supply device comprises a fuel cell device.
